(19) United States
(12) Patent Application Publication
(10) Pub. No.: US 2025/0210497 A1
(43) Pub. Date: Jun. 26, 2025

(54) SYSTEMS AND METHODS FOR POWER CONTROL IN 3D STACKED DIE

(71) Applicant: Advanced Micro Devices, Inc., Santa Clara, CA (US)

(72) Inventors: Stephen Dussinger, Ft. Collins, CO (US); Richard Martin Born, Ft. Collins, CO (US); Eric Busta, Ft. Collins, CO (US); Carson Donahue Henrion, Ft. Collins, CO (US); Jeffrey Lucas, Ft. Collins, CO (US); Alistair Tomlinson, Ft. Collins, CO (US); John Wuu, Ft. Collins, CO (US)

(73) Assignee: Advanced Micro Devices, Inc., Santa Clara, CA (US)

(21) Appl. No.: 18/395,111

(22) Filed: Dec. 22, 2023

(51) Int. Cl. H01L 23/498; H01L 23/00; H01L 25/065

(52) U.S. Cl. CPC H01L 23/49838; H01L 23/49816; H01L 23/49822; H01L 24/08; H01L 24/16; H01L 25/0652; H01L 2224/08137; H01L 2224/08146; H01L 2224/16104; H01L 2224/16146; H01L 2924/01013; H01L 2924/01029; H01L 2924/13091; H01L 2924/1427; H01L 2924/15311

(57) ABSTRACT

A method for controlling power in 3D stacked die can include configuring a first die of a set of 3D stacked die to receive power from a power source, wherein the first die includes one or more field effect transistors configured to control the power. The method can also include configuring one or more power domains included in a second die of the set of 3D stacked die to receive the power that is controlled by the one or more field effect transistors included in the first die. Various other methods and systems are also disclosed.

### BACKGROUND

A three-dimensional integrated circuit (3D IC) is a MOS (metal-oxide semiconductor) integrated circuit (IC) manufactured by stacking as many as 16 or more ICs and interconnecting them vertically using, for instance, through-silicon vias (TSVs) or Cu—Cu connections, so that they behave as a single device to achieve performance improvements at reduced power and smaller footprint than conventional two dimensional processes. The 3D IC is one of several 3D integration schemes that exploit the z-direction to achieve electrical performance benefits in microelectronics and nanoelectronics.

3D integrated circuits can be classified by their level of interconnect hierarchy at the global (package), intermediate (bond pad) and local (transistor) level. In general, 3D integration is a broad term that includes such technologies as 3D wafer-level packaging (3DWLP), 2.5D and 3D interposer-based integration, 3D stacked ICs (3D-SICs), 3D heterogeneous integration, and 3D systems integration as well as true monolithic 3D ICs.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for power control in 3D stacked die.

FIG. 2 is a block diagram of example semiconductor device circuitry for power control in 3D stacked die.

FIG. 3 is a block diagram of an example semiconductor device for power control in 3D stacked die.

FIG. 4 is a block diagram of an example semiconductor device package for power control in 3D stacked die.

FIG. 5 is a block diagram of example semiconductor device packages for power control in 3D stacked die.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for power control in 3D stacked die. For example, by configuring a first die of a set of 3D stacked die to receive power from a power source, wherein the first die includes one or more field effect transistors (FETs) configured to control the power, and configuring one or more power domains included in a second die of the set of 3D stacked die to receive the power that is controlled by the one or more field effect transistors included in the first die, various benefits can be achieved. For example, by locating one or more field effect transistors (e.g., gates, headers, power headers, PFETs (e.g., p-channel FETs, metal-oxide-semiconductor FETs (MOSFETs), etc.), etc.) in a near die (i.e., positioned closer to a package substrate than a far die) that gate and/or regulate power delivered to power domains and/or portions thereof that are located in the far die, power savings can be achieved in a 3D stacked device while avoiding the need for another power plane to be brought through a far die all the way down to the near die. Additional benefits can include the ability to gate and/or regulate power to power domains and/or portions of those domains in the far die. Costs savings and reduction of resource consumption (e.g., chip area) can be achieved compared to the alternative of adding an additional power plane.

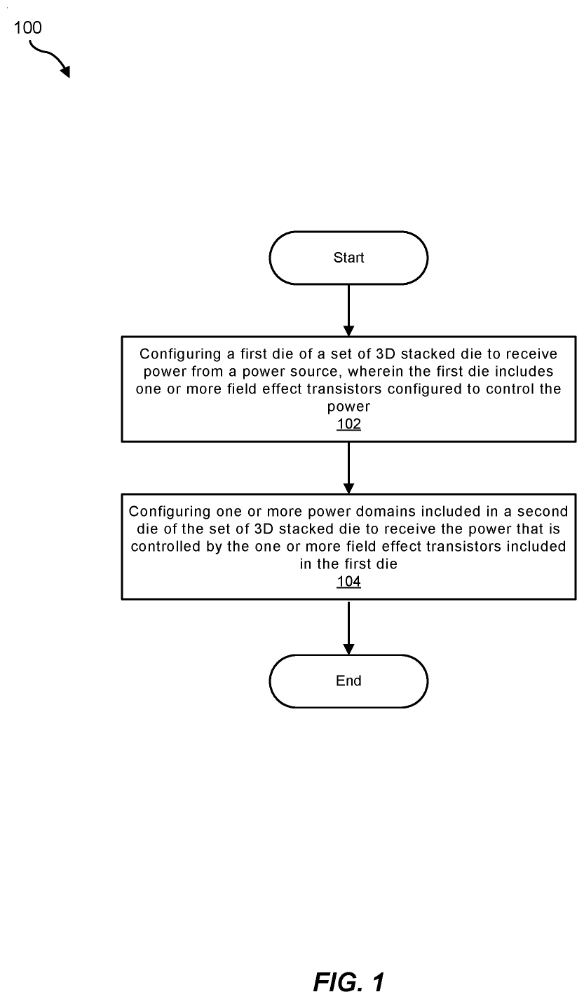

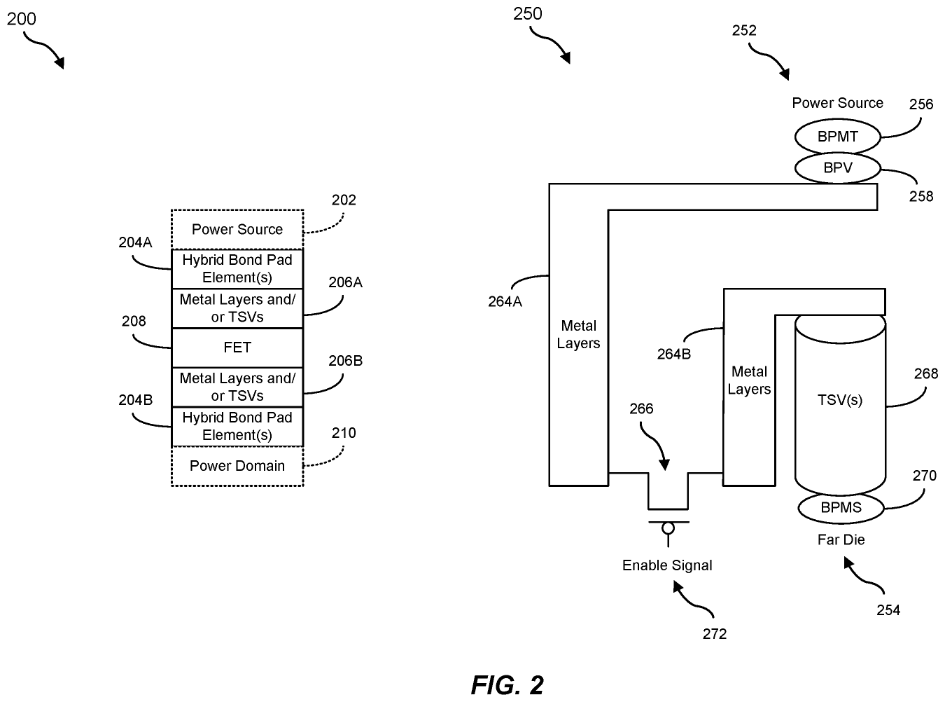

The following will provide, with reference to FIG. 1 detailed descriptions of example methods for power control in 3D stacked die. Detailed descriptions of corresponding semiconductor device circuitry, semiconductor devices, and semiconductor device packages will also be provided in connection with FIGS. 2-5.

In one example, a semiconductor device can include a first die of a set of 3D stacked die that is configured to receive power from a power source and that includes one or more field effect transistors configured to control the power, and a second die of the set of 3D stacked die that includes one or more power domains that are configured to receive the power that is controlled by the one or more field effect transistors included in the first die.

Another example can be the previously described example semiconductor device, wherein the power source corresponds to at least one of an additional die or a package substrate.

Another example can be any of the previously described example semiconductor devices, wherein the first die includes one or more through silicon vias that are configured to convey the power that is controlled by the one or more field effect transistors to the one or more power domains, and one or more metal layers that are configured to convey the power received from the power source through the one or more field effect transistors to one or more through silicon vias.

Another example can be any of the previously described example semiconductor devices, wherein the second die is stacked atop the first die in the set of 3D stacked die.

Another example can be any of the previously described example semiconductor devices, wherein a portion of a power domain of the one or more power domains is configured to receive the power that is controlled by the one or more field effect transistors included in the first die.

Another example can be any of the previously described example semiconductor devices, wherein the one or more field effect transistors include at least one of one or more gates, one or more power headers, one or more p-channel field effect transistors, or one or more metal-oxide-semiconductor field effect transistors.

Another example can be any of the previously described example semiconductor devices, wherein a set of two or more field effect transistors of the one or more field effect transistors are ganged together and configured to regulate the power to a same power domain by enabling only a proper subset of the set of two or more field effect transistors.

In one example, a semiconductor device package can include a power source and a set of 3D stacked die including a first die that is configured to receive power from the power source and that includes one or more field effect transistors configured to control the power, and a second die that includes one or more power domains configured to receive the power that is controlled by the one or more field effect transistors included in the first die, wherein the first die is positioned closer to the power source than the second die.

Another example can be the previously described example semiconductor device package, wherein the power source corresponds at least one of an additional die or a package substrate.

Another example can be any of the previously described example semiconductor device packages, wherein the first die is connected on a first side thereof to the power source, and the first die is connected to the second die by hybrid bonds on a second side thereof that is opposite to the first side.

Another example can be any of the previously described example semiconductor device packages, wherein the first die includes one or more through silicon vias that are configured to convey the power that is controlled by the one or more field effect transistors to the one or more power domains and one or more metal layers configured to convey the power that is received from the power source through the one or more field effect transistors to the one or more through silicon vias.

Another example can be any of the previously described example semiconductor device packages, wherein a portion of a power domain of the one or more power domains is configured to receive the power that controlled by the one or more field effect transistors included in the first die.

Another example can be any of the previously described example semiconductor device packages, wherein the one or more field effect transistors include at least one of one or more gates, one or more power headers, one or more p-channel field effect transistors, or one or more metal-oxide-semiconductor field effect transistors.

Another example can be any of the previously described example semiconductor device packages, wherein a set of two or more field effect transistors of the one or more field effect transistors are ganged together and configured to regulate the power to a same power domain by enabling only a proper subset of the set of two or more field effect transistors.

In one example, a method can include configuring a first die of a set of 3D stacked die to receive power from a power source, wherein the first die includes one or more field effect transistors configured to control the power, and configuring one or more power domains included in a second die of the set of 3D stacked die to receive the power that is controlled by the one or more field effect transistors included in the first die.

Another example can be the previously described example method, wherein the power source corresponds to at least one of an additional die or a package substrate.

Another example can be any of the previously described example methods, wherein configuring the first die includes configuring one or more through silicon vias to convey the power that is controlled by the one or more field effect transistors to the one or more power domains and configuring one or more metal layers to convey the power received from the power source through the one or more field effect transistors to the one or more through silicon vias.

Another example can be any of the previously described example methods, wherein configuring the one or more power domains includes stacking the second die atop the first die in the set of 3D stacked die.

Another example can be any of the previously described example methods, wherein configuring the one or more power domains includes configuring a portion of a power domain of the one or more power domains to receive the power that is controlled by the one or more field effect transistors included in the first die.

Another example can be any of the previously described example methods, wherein the one or more field effect transistors include at least one of one or more gates, one or more power headers, one or more p-channel field effect transistors, or one or more metal-oxide-semiconductor field effect transistors.

FIG. 1 is a flow diagram of an example method 100 for power control in 3D stacked die. As illustrated in FIG. 1, at step 102 one or more of the systems described herein can configure a first die. For example, step 102 can include configuring a first die of a set of 3D stacked die to receive power from a power source, wherein the first die includes one or more field effect transistors configured to control the power.

The term “die,” as used herein, can generally refer to a small block of semiconducting material on which a given functional circuit is fabricated. For example, and without limitation, integrated circuits can be produced in large batches on a single wafer of electronic-grade silicon (EGS) or other semiconductor (e.g., GaAs) through processes such as photolithography. The wafer can be cut (diced) into many pieces, each containing one copy of the circuit. Each of these pieces can be called a die.

The term “3D stacked die,” as used herein, can generally refer to die that are interconnected vertically. For example, and without limitation, vertical interconnection of stacked die can be implemented using, for instance, through-silicon vias (TSVs) or Cu-Cu connections, so that the 3D stacked die behave as a single device to achieve performance improvements at reduced power and smaller footprint than conventional two dimensional processes.

The term “power,” as used herein, can generally refer to a rate of electrical energy transfer by an electric circuit per unit of time. For example, and without limitation, power can be denoted by P and measured using an SI unit of power corresponding to one watt or one joule per second. Electric power can commonly be supplied by electric batteries and produced by electric generators.

The term “power source,” as used herein, can generally refer to a material component of a semiconductor device and/or semiconductor device package that provides electrical connection between a chip and different circuits (e.g., of a printed circuit board). For example, and without limitation, a power source can correspond to a package substrate, an additional die (e.g., an active interposer die, a lower stacked die in a 3D stack, etc.), etc.

The term “field effect transistor,” as used herein, can generally refer to a device that can control current flow. For example, and without limitation, field effect transistor (FET) can refer to one or more gates, one or more power headers, one or more power channel (p-channel) FETs (PFETS), and/or one or more metal-oxide-semiconductor (MOS) FETs (MOSFETs). In this context, a conductance configurable header can vary conductance in response to an enable signal received on an input (e.g., transistor leg) of the device. In some implementations, a header can include a collection of such devices. For example, and without limitation, a PFET can correspond to a collection (e.g., an array) of FETs.

The term “control,” as used herein, can generally refer to gating and/or regulating the output of a supply voltage. For example, and without limitation, control can correspond to enabling and/or disabling one or more field effect transistors to gate or ungate a power channel (e.g., TSV) to a power domain, enabling or disabling a proper subset of ganged field effect transistors to adjust resistance across a set of power channels (e.g., TSVs) to a same power domain, etc.

The systems described herein can perform step 102 in a variety of ways. In one example, the power source corresponds to at least one of an additional die or a package substrate. Additionally or alternatively, configuring the first die at step 102 can include configuring one or more through silicon vias to convey the power that is controlled by the one or more field effect transistors to one or more power domains of a second die and configuring one or more metal layers to convey the power received from the power source through the one or more field effect transistors to the one or more through silicon vias. In some implementations, the one or more field effect transistors can include one or more gates, one or more power headers, one or more p-channel field effect transistors, and/or one or more metal-oxide-semiconductor field effect transistors. In some examples, a set of two or more field effect transistors of the one or more field effect transistors can be ganged together and configured to regulate the power to a same power domain by enabling only a proper subset of the set of two or more field effect transistors.

The term “additional die,” as used herein, can generally refer to a die in a 3D stack or connected to the 3D stack. For example, and without limitation, an additional die can correspond to an active interposer die, any lower stacked die in a 3D stack, etc. In this context, an active interposer can correspond to a bottom circuit die in a stacked circuit die configuration. For example, and without limitation, an active interposer die can be used to integrate flexible and distributed interconnect fabrics for scalable chiplet traffic, energy-efficient 3D-plugs using fine pitch interconnects, power management features for power supply closer to the cores, and memory-IO controller and PHY for off-chip communication.

The term “package substrate,” as used herein, can generally refer to a (e.g., flat) piece of insulator on which an integrated circuit can be mounted. For example, and without limitation, input and output pins of an integrated circuit can be individually connected (e.g., by wire bonding or bump bonding) to metal leads on the substrate. These leads can connect the integrated circuit to other parts of the package.

The term “through silicon via,” as used herein, can generally refer to metalized holes or pillars providing a vertical interconnect between individual, stacked wafers and/or individual, stacked dies to form customized, multilayer, multifunctional devices. For example, and without limitation, through silicon vias can completely pass through a silicon die or wafer to allow for stacking of silicon die.

The term “metal layer,” as used herein, can generally refer to wiring in and/or on a wafer and/or chip that interconnects individual devices (e.g., transistors, capacitors, resistors, etc.) of an integrated circuit. For example, and without limitation, a metal layer can include copper and/or aluminum.

The term “gate,” as used herein, can generally refer to a device that can switch a channel on or off or the act of switching a channel on or off. For example, and without limitation, a PFET can correspond to a gate that is closed in response to a low enable signal (e.g., a zero) and open in response to a high enable signal (e.g., a one).

The term “p-channel,” as used herein, can generally refer to using hole flow as a charge carrier. For example, and without limitation, a p-channel MOSFET can correspond to a type of MOSFET in which the channel is composed with a majority of charge carriers as holes (e.g., as opposed to using electron flow as a charge carrier as with n-channel MOSFETS). Once a p-channel MOSFET is activated, then the majority of charge carriers like holes can move throughout the channel.

The term “metal oxide semiconductor,” as used herein, can generally refer to a three-layer sandwich of a metal, an insulator (e.g., an oxide of a substrate), and a semiconductor substrate, used in integrated circuits. For example, and without limitation, a MOSFET can correspond to a type of FET often fabricated by controlled oxidation of silicon and having an insulated gate, the voltage of which determines the conductivity of the device.

The term “ganged together,” as used herein, can generally refer to grouping of field effect transistors and TSVs. For example, and without limitation, field effect transistors and TSVs can be configured to provide power in parallel to a same power domain, and thus be ganged together. In this context, power regulation for that power domain can be accomplished by enabling a proper subset of the field effect transistors that are ganged together.

The term “regulate,” as used herein, can generally refer to reducing supplied power only partially, as opposed to gating it by reducing the supplied power to zero. For example, and without limitation, field effect transistors and TSVs can be configured to provide power in parallel to a same power domain so that power regulation for that power domain can be accomplished by enabling a proper subset of the field effect transistors that are ganged together in this manner.

The term “enabling,” as used herein, can generally refer to turning on a device. For example, and without limitation, a FET can be enabled by an enable signal (e.g., a logical one or a logical zero) provided to an input (e.g., a transistor leg) of the header.

The term “proper subset,” as used herein, can generally refer to a subset of a set that is not equal to the set. For example, and without limitation, a set can include all of the elements of its subsets, and any subset that excludes at least one element of the set can correspond to a proper subset of the set. In this context, a proper subset of a set of ganged field effect transistors includes only field effect transistors that are members of the set but does not include all field effect transistors of the set.

At step 104 one or more of the systems described herein can configure one or more power domains. For example, step 104 can include configuring one or more power domains included in a second die of the set of 3D stacked die to receive the power that is controlled by the one or more field effect transistors included in the first die.

The term “power domain,” as used herein, can generally refer to a collection of devices that use a same power supply during normal operation and that can be switched on or off at a same time. For example, and without limitation, a power domain can correspond to an individual processor core, such as a processing unit among multiple processing units of a multi-core processor corresponding to a microprocessor on a single integrated circuit.

The systems described herein can perform step 104 in a variety of ways. In one example, configuring the one or more power domains at step 104 can include stacking the second die atop the first die in the set of 3D stacked die. Additionally or alternatively, configuring the one or more power domains at step 104 can include configuring a portion of a power domain of the one or more power domains to receive the power that is controlled by the one or more field effect transistors included in the first die.

The term “stacking,” as used herein can generally refer to 3D integrated circuit manufacture processes that build one semiconductor layer (e.g., die or wafer) atop another. For example, and without limitation, stacking procedures can include die-to-die stacking, die-to-wafer stacking, and/or wafer-to-wafer stacking. In die-to-die stacking, electronic components are built on multiple die that are then aligned and bonded to one another. In die-to-wafer stacking, electronic components are built on two or more semiconductor wafers; one wafer is diced, and the resulting die are then aligned and boded onto die sites of the other wafer. In wafer to wafer stacking, electronic components are built on two or more semiconductor wafers that are then aligned, bonded, and diced into 3D integrated circuits.

Referring to FIG. 2, example semiconductor device circuitry 200 and 250 for power control in 3D stacked die can be implemented in the first die configured in step 102 of FIG. 1. Semiconductor device circuitry 200 can include hybrid bond pad elements 204A and 204B, such as one or more bond pad metal tops, one or more bond pad vias, and one or more bond pad metal substrates. Semiconductor device circuitry 200 can also include one or more metal layers and/or through silicon vias (TSVs) 206A and 206B. The metal layers can include one or more redistribution layers, one or more redistribution layer vias, and/or one or more power planes located in a near die that can correspond to the first die configured in step 102 of FIG. 1. Semiconductor device circuitry 200 can further include one or more power field effect transistors 208. The hybrid bond pad elements 204A and 204B and one or more metal layers and/or through silicon vias (TSVs) 206A and 206B can be arranged to convey power supplied by a power source 202 through the one or more power field effect transistors 208 before it is to one or more power domains 210. The one or more power domains 210 can be located in a far die that can correspond to the second die referenced in step 104 of FIG. 1. The one or more power field effect transistors 208 can control the conveyed power in response to an enable signal by switching on and/or off, thus controlling and/or regulating the power supplied from the power source 202 to the one or more power domains 210.

Semiconductor device circuitry 250 can correspond to an implementation of semiconductor device circuitry 200. Semiconductor device circuitry 250 can control power supplied by a power source 252 and delivered to a far die 254 that can correspond to the second die referenced in step 104 of FIG. 1. For example, power supplied by a power source 252 can be conveyed through a bond pad metal top 256 (BPMT) and a bond pad via 258 (BPV) to one or more metal layers 264A and 264B, which can include one or more redistribution layers, one or more redistribution layer vias, and/or one or more power planes located in a near die that can correspond to the first die configured in step 102 of FIG. 1. Metal layers 264A and 264B can convey the power that is received from the power source 252 through one or more field effect transistors 266 that control the supplied power to one or more through silicon vias 268. The one or more through silicon vias 268 can convey the power that is controlled by the one or more field effect transistors 266 through a bond pad metal substrate 270 (BPMS) to one or more power domains in the far die 254. One or more field effect transistors 266 can respond to an enable signal 272 by switching on and/or off, thus controlling and/or regulating the power supplied from the power source 252 to the far die 254.

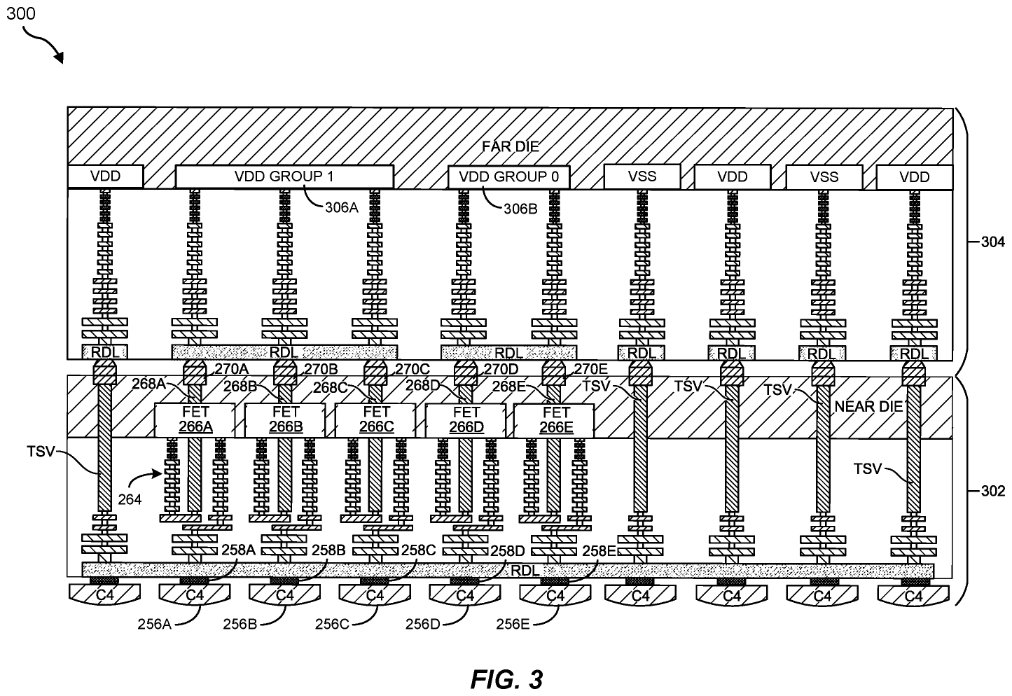

Referring to FIG. 3, an example semiconductor device 300 for power control in 3D stacked die can include a near die 302 and a far die 304 that includes power domains 306A and 306B. The far die 304 can correspond to the second die referenced in step 104 of FIG. 1 and can be stacked atop the near die 302, which can correspond to the first die configured in step 102 of FIG. 1. The near die 302 and the far die 304 can be configured for attachment to a power source in a manner that positions the near die 302 closer to the power source than the far die 304. This configuration can yield various benefits, including improved thermal performance for various power domains, including power domains 306A and 306B, in the far die. Additionally, near die 302 can include numerous TSVs and these TSVs can include TSVs 268A-268E that are ganged together. For example, TSVS 268A-268C can be ganged together to supply power to power domain 306A and TSVs 268D and 268E can be ganged together to supply power to power domain 306B. Providing multiple TSVs in this manner can further deliver higher quality power because more TSVs yield a more robust power delivery.

The term “near die,” as used herein, can generally refer to any die of a 3D stack that includes power control circuitry as disclosed herein and that is configured for location closer to a power source than a far die containing one or more power domains that receive power controlled by the power control circuitry in the near die, as disclosed herein. For example, and without limitation, a near die can contain additional circuit elements of a semiconductor circuit, such as memory (e.g., SRAM, DRAM, etc.), additional power domains, sensors, and/or any other type of semiconductor circuitry.

The term “far die,” as disclosed herein, can generally refer to any die of a 3D stack that includes one or more power domains that receive power controlled by power control circuitry in a near die, as disclosed herein. For example, and without limitation, a far die can contain additional circuit elements of a semiconductor circuit, such as memory (e.g., SRAM, DRAM, etc.), additional power domains, sensors, and/or any other type of semiconductor circuitry.

Each of TSVs 268A-268E can be included in power control circuitry as described with reference to FIG. 2. For example, BPMTs 256A-256E and BPVs 258A-258E can convey supplied power to a redistribution layer (RDL) and its redistribution layer vias (RV) s to metal layers 264 as shown. These metal layers 264 can convey the power that is received from the power source through field effect transistors 266A-266E that control the power supplied to TSVs 268A-268E. The TSVs 268A-268E can convey the power that is controlled by the field effect transistors 266A-266E through BPMSs 270A-270E to the power domains 306A and 306B in the far die 304.

Since TSVs 268A-268C can be ganged together to supply power to power domain 306A, field effect transistors 266A-266C can control the power supplied to power domain 306A. For example, power supplied to power domain 306A can be gated (e.g., switched on or off) by enabling and disabling an entire set of field effect transistors 266A-266C. Alternatively or additionally, power supplied to power domain 306A can be regulated (e.g., partially increased or partially decreased) by enabling and disabling (e.g., switching on or off) a proper subset of field effect transistors 266A-266C. For examples, switching off only one or two of field effect transistors 266A-266C can increase resistance and thus decrease inline voltage supplied to power domain 306A.

Likewise, since TSVs 268D and 268E can be ganged together to supply power to power domain 306B, field effect transistors 266D and 266E can control the power supplied to power domain 306B. For example, power supplied to power domain 306B can be gated (e.g., switched on or off) by enabling and disabling an entire set of field effect transistors 266D and 266E. Alternatively or additionally, power supplied to power domain 306B can be regulated (e.g., partially increased or partially decreased) by enabling and disabling (e.g., switching on or off) a proper subset of field effect transistors 266D and 266E. For example, switching off only one of field effect transistors 266D and 266E can increase resistance and thus decrease inline voltage supplied to power domain 306B.

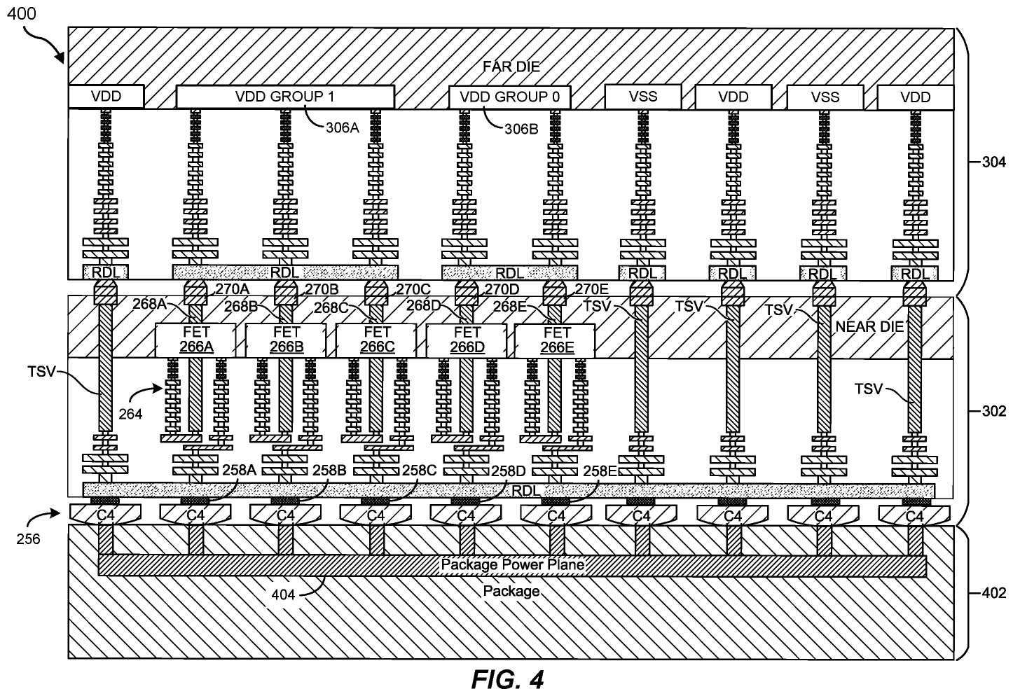

Referring to FIG. 4, an example semiconductor device package 400 for power control in 3D stacked die can include the near die 302 and the far die 304 having features as described with reference to FIGS. 2 and 3. For example, far die 304 can include power domains 306A and 306B and near die can include TSVs 268A-268E, BPMTs 256, BPVs 258A-258E, RDL, metal layers 264, field effect transistors 266A-266E, and BPMSs 270A-270E. Additionally, semiconductor device package 400 can include a power source 402 that can correspond to a package substrate including a package power plane 404. BPMTs 256 can connect to the power plane 404 of the power source 402 so that power supplied by the power source 402 can be controlled by the field effect transistors 266A-266E as described herein.

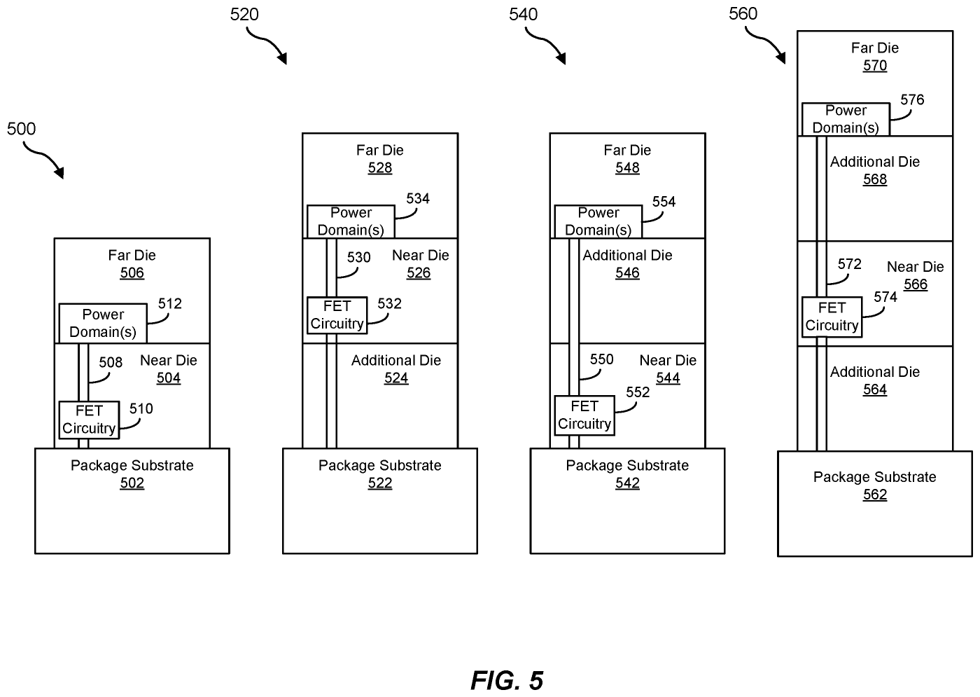

Referring to FIG. 5, example semiconductor device packages 500, 520, 540, and 560 demonstrate various package configurations that implement power control in 3D stacked die. For example, semiconductor device package 500 can include a package substrate 502 having a set of 3D stacked die thereon, such as a near die 504 and a far die 506. In the example package 500, the package substrate 502 can correspond to a power source and the near die 504 can include one or more TSVs 508 having FET circuitry 510 that controls power supplied by the package substrate to one or more power domains 512 in the far die 506.

In another example, semiconductor device package 520 can include a package substrate 522 having a set of 3D stacked die thereon, such as one or more additional die 524 positioned on the package substrate and a near die 526 and a far die 528 stacked atop the one or more additional die 524. In the example package 520, the package substrate 522 and/or the one or more additional die 524 can correspond to a power source and the near die 526 can include one or more TSVs 530 having FET circuitry 532 that controls power supplied by the power source to one or more power domains 534 in the far die 528.

In another example, semiconductor device package 540 can include a package substrate 542 having a set of 3D stacked die thereon, such as a near die 544, one or more additional die 546 stacked above the near die 544, and a far die 548 stacked atop the one or more additional die 546. In the example package 540, the package substrate 542 can correspond to a power source and the near die 544 can include one or more TSVs 550 having FET circuitry 552 that controls power supplied by the power source to one or more power domains 554 in the far die 548. The one or more additional die 546 can correspond to one or more additional near die, one or more additional far die, and/or any other additional die of a 3D stack.

In another example, semiconductor device package 560 can include a package substrate 562 having a set of 3D stacked die thereon, such as one or more additional die 564 positioned on the package substrate 562, a near die 566 stacked atop the one or more additional die 564, one or more additional die 568 stacked above the near die 566, and a far die 570 stacked atop the one or more additional die 568. In the example package 560, the package substrate 562 and/or the one or more additional die 564 can correspond to a power source. Also, the near die 566 can include one or more TSVs 572 having FET circuitry 574 that controls power supplied by the power source to one or more power domains 576 in the far die 570. The one or more additional die 568 can correspond to one or more additional near die, one or more additional far die, and/or any other additional die of a 3D stack.

As set forth above, the disclosed systems and methods can configure a first die of a set of 3D stacked die to receive power from a power source, wherein the first die includes one or more field effect transistors configured to control the power, and configure one or more power domains included in a second die of the set of 3D stacked die to receive the power that is controlled by the one or more field effect transistors included in the first die. In this way, the disclosed systems and methods can achieve various benefits. For example, by locating one or more field effect transistors (e.g., gates, power headers, PFETs (e.g., p-channel FETs, metal-oxide-semiconductor FETs (MOSFETs), etc.), etc.) in a near die (i.e., positioned closer to a package substrate than a far die) that gate and/or regulate power delivered to power domains and/or portions thereof that are located in the far die, power savings can be achieved in a 3D stacked device while avoiding the need for another power plane to be brought through a far die all the way down to the near die. Additional benefits can include the ability to gate and/or regulate power to power domains and/or portions of those domains in the far die. Costs savings and reduction of resource consumption (e.g., chip area) can be achieved compared to the alternative of adding an additional power plane.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
a first die of a set of 3D stacked die that is configured to receive power from a power source and that includes one or more field effect transistors configured to control the power; and
a second die of the set of 3D stacked die that includes one or more power domains that are configured to receive the power that is controlled by the one or more field effect transistors included in the first die.

2. The semiconductor device of claim 1, wherein the power source corresponds to at least one of an additional die or a package substrate.

3. The semiconductor device of claim 1, wherein the first die includes:
one or more through silicon vias that are configured to convey the power that is controlled by the one or more field effect transistors to the one or more power domains; and
one or more metal layers that are configured to convey the power received from the power source through the one or more filed effect transistors to one or more through silicon vias.

4. The semiconductor device of claim 1, wherein the second die is stacked atop the first die in the set of 3D stacked die.

5. The semiconductor device of claim 1, wherein a portion of a power domain of the one or more power domains is configured to receive the power that is controlled by the one or more field effect transistors included in the first die.

6. The semiconductor device of claim 1, wherein the one or more field effect transistors include at least one of one or more gates, one or more power headers, one or more p-channel field effect transistors, or one or more metal-oxide-semiconductor field effect transistors.

7. The semiconductor device of claim 1, wherein a set of two or more field effect transistors of the one or more field effect transistors are ganged together and configured to regulate the power to a same power domain by enabling only a proper subset of the set of two or more field effect transistors.

8. A semiconductor device package, comprising:
a power source; and
a set of 3D stacked die including:
a first die that is configured to receive power from the power source and that includes one or more field effect transistors configured to control the power; and
a second die that includes one or more power domains configured to receive the power that is controlled by the one or more field effect transistors included in the first die, wherein the first die is positioned closer to the power source than the second die.

9. The semiconductor device package of claim 8, wherein the power source corresponds at least one of an additional die or a package substrate.

10. The semiconductor device package of claim 8, wherein:
the first die is connected on a first side thereof to the power source; and
the first die is connected to the second die by hybrid bonds on a second side thereof that is opposite to the first side.

11. The semiconductor device package of claim 8, wherein the first die includes:
one or more through silicon vias that are configured to convey the power that is controlled by the one or more field effect transistors to the one or more power domains; and
one or more metal layers configured to convey the power that is received from the power source through the one or more field effect transistors to the one or more through silicon vias.

12. The semiconductor device package of claim 8, wherein a portion of a power domain of the one or more power domains is configured to receive the power that controlled by the one or more field effect transistors included in the first die.

13. The semiconductor device package of claim 8, wherein the one or more field effect transistors include at least one of one or more gates, one or more field effect transistors, one or more p-channel field effect transistors, or one or more metal-oxide-semiconductor field effect transistors.

14. The semiconductor device package of claim 8, wherein a set of two or more field effect transistors of the one or more field effect transistors are ganged together and configured to regulate the power to a same power domain by enabling only a proper subset of the set of two or more field effect transistors.

15. A method, comprising:
configuring a first die of a set of 3D stacked die to receive power from a power source, wherein the first die includes one or more field effect transistors configured to control the power; and
configuring one or more power domains included in a second die of the set of 3D stacked die to receive the power that is controlled by the one or more field effect transistors included in the first die.

16. The method of claim 15, wherein the power source corresponds to at least one of an additional die or a package substrate.

17. The method of claim 15, wherein configuring the first die includes:
configuring one or more through silicon vias to convey the power that is controlled by the one or more field effect transistors to the one or more power domains; and
configuring one or more metal layers to convey the power received from the power source through the one or more field effect transistors to the one or more through silicon vias.

18. The method of claim 15, wherein configuring the one or more power domains includes stacking the second die atop the first die in the set of 3D stacked die.

19. The method of claim 15, wherein configuring the one or more power domains includes configuring a portion of a power domain of the one or more power domains to receive the power that is controlled by the one or more field effect transistors included in the first die.

20. The method of claim 15, wherein the one or more field effect transistors include at least one of one or more gates, one or more field effect transistors, one or more p-channel field effect transistors, or one or more metal-oxide-semiconductor field effect transistors.
